(19) United States
(12) Patent Application Publication
(10) Pub. No.: US 2018/0047479 A1
(43) Pub. Date: Feb. 15, 2018

(54) TWIN-AXIAL CABLE WITH INCREASED COUPLING

(71) Applicant: LOROM AMERICA, Morrisville, NC (US)

(72) Inventors: Henning HANSEN, Pittsboro, NC (US); Patrick CASHER, North Aurora, IL (US)

(73) Assignee: LOROM AMERICA, Morrisville, NC (US)

(21) Appl. No.: 15/672,946

(22) Filed: Aug. 9, 2017

Related U.S. Application Data
(60) Provisional application No. 62/372,435, filed on Aug. 9, 2016.

(51) Int. Cl. H01B 7/02; H01B 11/00; H01B 13/22; H05K 9/00; H01B 13/08

(52) U.S. Cl. CPC H01B 7/0216; H05K 9/0098; H01B 13/08; H01B 13/22; H01B 11/002

(57) ABSTRACT

A twin-axial cable includes (1) a first primary comprising a first signal conductor surrounded by a dielectric and (2) a second primary comprising a second signal conductor surrounded by a dielectric. The twin-axial cable also includes a different dielectric is wrapped around the exterior of both of the first and second primaries.

### CROSS-REFERENCE TO RELATED APPLICATION

This nonprovisional application claims the benefit of U.S. Provisional Application No. 62/372,435, filed Aug. 9, 2016. The disclosure of the prior application is hereby incorporated by reference herein in its entirety.

### BACKGROUND

Cables are used for various applications. For example, some cables, such as twin-axial cables have been used for telecommunications. Conventional twin-axial constructions (as shown in FIG. 1) include the “primaries”, a foil shield, a drain wire and an outer adhesive tape. The drain wire can be inside or outside the foil shield. The drain wire can be round or flat. There can be 1 or 2 drain wires.

The center-to-center spacing and the distance from the signal conductor to the foil shield have a fixed distance. This structure has only the ability to tune either differential or common mode impedance but not both. Typically the differential mode impedance is tuned to 100 ohms and the common mode impedance is untunable.

The diameter of the “primary's” insulation is a function of the insulation materials dielectric properties and the desired differential mode impedance. The diameter is decreased to reduce differential impedance and increased to raise differential impedance. The common mode impedance is linked but not independently tunable.

Another method of controlling the center-to-center distance between two wires is to include both wires within one extruded insulation. This would also allow the differential and common mode impedances to be to independently and thus resulting in a structure were the percent coupling can be tuned. However, there are manufacturing concerns with this. For example, the ability to control the spacing accurately under extrusion head pressures. In addition, of-the-shelf automation equipment for controlling the capacitance of the primaries cannot be used. It currently does not exist to support two wires in a single insulation.

### SUMMARY

Disclosed herein is a twin-axial cable construction that provides a lower insertion loss and the ability to decrease the center-to-center spacing, pitch, of the two signal wires.

In one embodiment, a twin-axial cable includes (1) a first primary comprising a first signal conductor surrounded by a dielectric and (2) a second primary comprising a second signal conductor surrounded by a dielectric. The twin-axial cable also includes a different dielectric is wrapped around the exterior of both of the first and second primaries.

In another embodiment, a twin axial cable may include a first cable comprising: a first conductor; a first dielectric surrounding the first conductor; a second cable aligned with the first cable and comprising: a second conductor; a second dielectric surrounding the second conductor; a third dielectric completely enclosing the first and second cables so that the third dielectric is not disposed between the first and second cables; and shielding disposed around the third dielectric.

In another embodiment, a twin axial cable may include a first conductor surrounded by a first dielectric; a second conductor surrounded by a second dielectric and is axially aligned with the first conductor so that the first dielectric is directly contacting the second dielectric along an axial length; a third dielectric enclosing the first and second cables but not disposed to increase a distance between the first and second conductors; and shielding disposed around the third dielectric.

In another embodiment, a method of manufacturing a twin axial cable, the method comprising: surrounding a first conductor with a first dielectric; surrounding a second conductor with a second dielectric; axially aligning the first and second conductors so that the first dielectric is directly contacting the second dielectric along an axial length; enclosing the first and second cables with a third dielectric so that the third dielectric is not disposed therebetween so as to not increase a distance between the first and second conductors; and disposing a shielding around the third dielectric.

### BRIEF DESCRIPTION OF THE DRAWINGS

Exemplary embodiments are described herein with reference to the following figures wherein:

FIG. 1 illustrates a conventional twin-axial construction.

FIGS. 2 and 3 illustrate a twin-axial construction according to one embodiment.

FIG. 4 illustrates a graph of cable loss measurement of an exemplary cable of the present disclosure and a conventional cable.

### DETAILED DESCRIPTION OF EMBODIMENTS

The following exemplary embodiments refer to the detecting and/or dispensing of fluid in a dispenser and removable container system by the use of hall effect sensors. It should be appreciated that, although the exemplary embodiments according to this disclosure can be applicable to specific applications, the depictions and/or descriptions included in this disclosure are not intended to be limited to any specific application. For example, the exemplary embodiments are not limited to a particular environment or use, and can be used for dispensing fluid in refrigerated storage, non-refrigerated storage, chilled storage, heated storage or storage at ambient conditions. A wide variety of fluids can be used in these conditions such as, for example, coffee, soft drinks and water. Accordingly, any system and method that can advantageously involve a dispenser and a removable container as described in an exemplary manner in this disclosure are contemplated.

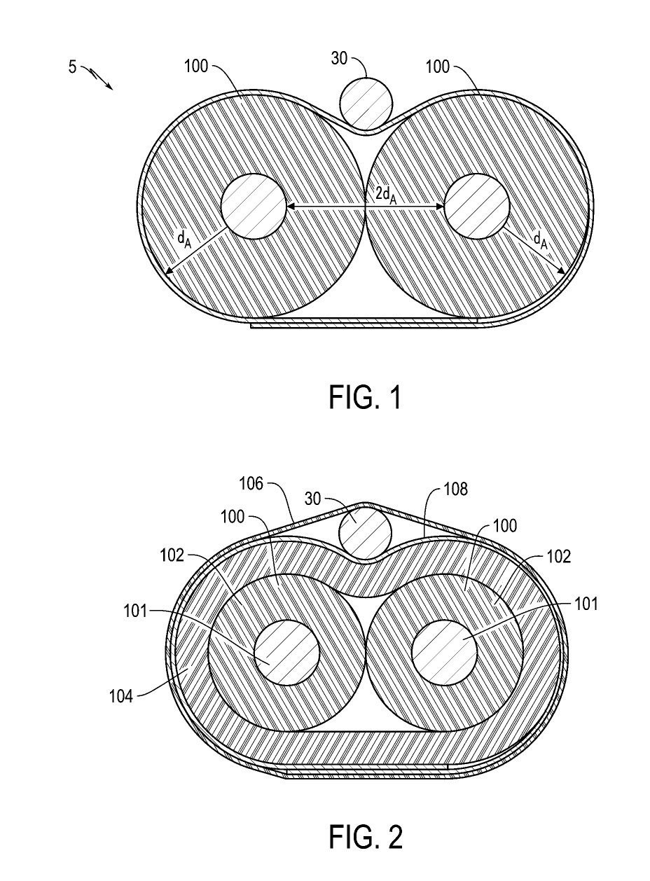

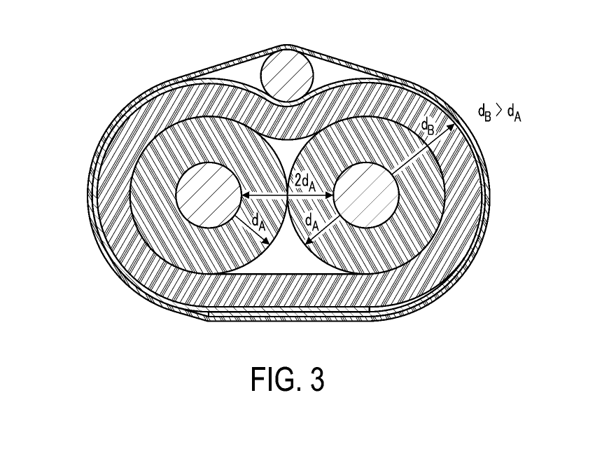

With reference to FIGS. 1 and 2, traditional twin-axial cables 100 include a pair of conductors 101, such as made of copper wire, with an insulator 102 surrounding each conductor and separating the conductors from each other by a center-to-center distance of 2 d_{A}. A shield 108 (e.g., a metallic foil screen) may be disposed around at least the two conductors and their respective insulators which are typically manufactured in extrusion lines. In some cases, one or more drains or grounding wires 30 may be placed in contact with the shield 108, as well. The diameter of each insulator, denoted by d_{A}, together define a total distance (2 d_{A}) between the two conductors, which is a parameter influencing the impedance and signal loss of the given cable 5. In particular, any changes in the distance as the signal pair is propagated over the length of the cable 5 may cause an increase in the noise that is experienced and may reduce the signal transmission efficacy.

In addition to the dimensional aspects of the cable 5, material selection also has an effect on signal quality. For example, the material used to make the insulator ideally should, at high frequencies, have minimal effect on the transmission efficacy of the signal propagated through the conductor. The transmission efficacy of the signal may be affected, for example, when the energy of the signal is dissipated as heat due to resonance at the molecular level. In conventional cables 5, polyethylene (PE) is typically chosen as the insulator 20, 25 because it exhibits good high frequency properties due to its low dielectric constant K (K of approximately 2.5) and low dissipation factor and can be extruded to form the cable according to conventional manufacturing methods. Other materials, such as polytetrafluoroethylene (PTFE), may be desirable for use as the insulator due to a low dielectric constant K (K of approximately 2.2 for PTFE) and low dissipation factor. In the case of PTFE, however, this material is more difficult to extrude than, for example, PE and is thus harder to manufacture. Moreover, materials that have even lower dielectric constants K, such as expanded PE (ePE), which is produced by applying heat, pressure, and a blowing agent to PE in the extrusion melt phase to create voids in the material and has a dielectric constant K of approximately 1.5, and expanded PTFE (ePTFE), which is produced by applying heat and quickly pulling the material to create voids and has a dielectric constant K of approximately 1.3, are even more difficult, if not impossible, to use for manufacturing a cable according to conventional methods.

According to one aspect, the twin-axial cable 5 includes signal conductors 101 and two different dielectrics 102, 104. As shown in FIG. 2, a first dielectric 102 (with a thickness d_{A}) is located directly on each of the signal conductors 101.

The combination of a signal conductor and its dielectric is commonly referred to as the “primary”. In twin-axes, the “primary” may be created by extrusion but it can also be created by other processes, such as by wrapping a dielectric tape around it.

Referring back to FIG. 2, a secondary dielectric 104 is added over the two “primaries”. This secondary dielectric is added as a tape 106 that is wrapped around the two “primaries”. The thickness of the first and secondary dielectrics are denoted as d_{B} (i.e., d_{A}+thickness of secondary dielectric), while maintain the same distance (2 d_{A}) between conductors if the secondary dielectric is not in the cable 5. The secondary dielectric completely surrounds both cables 100 so that the secondary dielectric is not disposed between these cables 100. In other words, the secondary dielectric may completely enclose both of the cables 100 and directly contact a portion of each of the primaries of each cable 5.

The secondary dielectric provides the lower loss by combination of three items. First, the secondary dielectric increases the signal-to-signal coupling by 8% to 17% over conventional twin-axial cable. Second, it increases the surface area of the shield 108 which reduces shield conduction losses. Finally, the signal wire diameter can be increased reducing the conduction losses in the signal wire.

At the fundamental frequencies associated with 25 and 28 Gbps applications, conduction losses in a cable assembly can constitute more the 80% of the total losses in a twin-axial cable. The conductors that contribute to these losses are the two signal wires and the foil shield used for ground. The two signal conductors typically contribute more than 65% of the total losses and the foil shield contributes more than 15% of the total losses. Their conductivity loss is a function of the metal conductivity including its surface roughness but primarily of their surface area of the metal. The larger the surface area the lower the conductivity losses.

Thus a structure where the surface area of either the signal conductors or the shield can be increased while maintaining center-to-center spacing.

Percentage coupling is calculated from the differential and common mode impedance. A higher percentage coupling indicates more coupling between the two signal wires and less to the shield. Conversely, a lower percentage coupling indicates more coupling to the shield and less between the signal wires. The percent coupling is calculated from using a ratio. With the difference between the even mode and odd mode impedance in the numerator and the sum of the even and odd mode impedance in the denominator. The even mode impedance is a function of the common mode impedance, twice the common mode impedance. The odd mode impedance is a function of the differential mode impedance, half the differential mode impedance. Conventional twin-axial has a common mode impedance around 28 ohms which gives a percent coupling of 6%. This twin-axial construction has a common mode impedance that can be tuned to give a desired percent coupling. Typically the common mode impedance is tuned from 33 to 40 ohms which gives a percent coupling range from 14 to 23%.

Coupling of two wires, “differential mode”, can decrease differential insertion loss. It will be less than that of the same two wires when they are uncoupled, “single-ended”. Thus tighter coupling of wires is desirable.

The wire diameter is typically increased (wire gauge decreased) to reduce insertion losses. However, prior to the present disclosure, this results in an increased wire pitch, center-to-center spacing, to maintain the desired differential impedance. With this disclosure, as shown in FIG. 3, signal wire diameter can be increased while maintaining center-to-center spacing. Thus a lower loss 28 awg cable can be used in an application designed for a 30 awg cable center-to-center spacing. This would normally reduce differential impedance lower than the desired values. In this disclosure, the differential impedance can be maintained by moving the shield further out. The result would only be an increased the common mode signals impedance.

Features & Benefits

Lower Differential Mode Insertion Loss

Tighter and variable center-to-center spacing of signal conductors

Ability to Independently Tune Differential and Common Mode Impedances (% coupling)

Increased Common Mode (undesired mode) Insertion Loss

### ALTERNATE EMBODIMENTS

The above embodiment discussed above (“the above-disclosed construction embodiment”) is an exemplary embodiment and there are alternate/modified embodiments, some of which are disclosed below.

In another embodiment, the above-disclosed construction embodiment may have the drain or grounding wire 30 located radially “inside” the shield 108 or outer foil but is radially outside of the secondary dielectric 104.

In yet another embodiment, the above-disclosed construction embodiment may have the drain or grounding wire 30 located radially “inside” the secondary dielectric 104.

In still yet another embodiment, the above-disclosed construction embodiment may have a flat drain or grounding wire 30.

In yet another embodiment, the above-disclosed construction embodiments may have two drain or grounding wires 30. These drain wires would be located symmetrically with respect to the signal wires: either in the top and bottom interstices of left and right. These drain or grounding wires 30 can be round, flat or some shape in between.

In yet another embodiment, above-disclosed construction embodiment may use a “skin-foam-skin” for the “primaries” insulation. In one embodiment, skin-foam-skin is an insulation that consists of three layers extruded together, where the first layer is a solid material, the second layer is a foamed material and the outer layer is again a solid material.

In yet another embodiment, above-disclosed construction embodiment may be instead tuned to 85 ohms differentially and with a percentage coupling still between 14 and 23%. In this embodiment, the common mode impedance would be between 28 and 34 ohms.

It should be noted that the dielectric materials for the primaries may be low or high-density polyethylene (LDPE/HDPE), a blend of both LDPE & HDPE, fluorinated ethylene propylene FEP, according to some embodiments. In other embodiments, the dielectric materials could be polytetrafluoroethylene (PTFE) or perfluoroalkoxy PFA.

The dielectric material for the outer tape dielectric could also be the same materials as the dielectric materials for the primaries.

In one embodiment, polyethylene could be used for the primaries and expanded PTFE (ePTFE) for the tape.

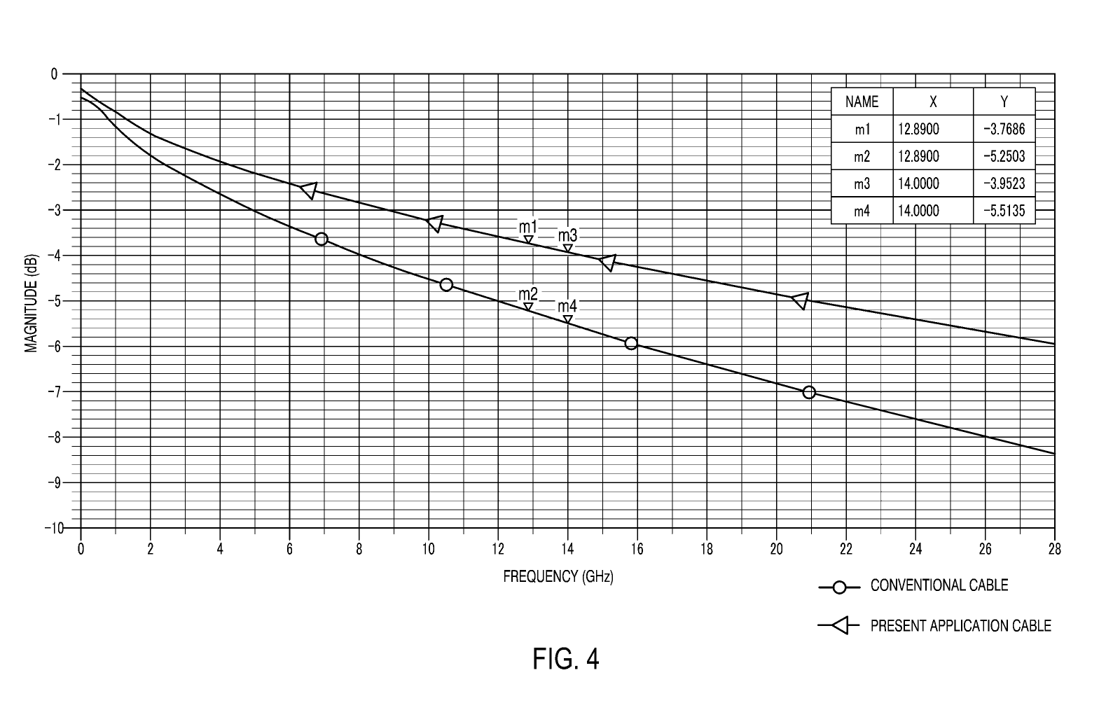

FIG. 4 illustrates a graph of cable loss measurement of an exemplary cable of the present disclosure and a conventional cable. The cable loss is indicated on FIG. 4 at two particular frequencies: 12.89 GHz and 14.0 GHz. At 12.89 GHz and 14.0 GHz, the cable losses are −3.8 dB and −4 dB, respectively, for a cable according to an embodiment of the present application, as compared with −5.3 dB and −5.5 dB, respectively, for a conventional cable. Accordingly, the performance of the cable of the present disclosure with the features discussed above outperforms conventional cables without these features.

It should be appreciated that various features disclosed above and other features and functions, or alternatives thereof, may be desirably combined into many other devices. Also, various alternatives, modifications, variations or improvements therein may be subsequently made by those skilled in the art, which are also intended to be encompassed by this disclosure.

What is claimed is:

1. A twin axial cable comprising:
a first cable comprising:
a first conductor;
a first dielectric surrounding the first conductor;
a second cable aligned with the first cable and comprising:
a second conductor;
a second dielectric surrounding the second conductor;
a third dielectric completely enclosing the first and second cables so that the third dielectric is not disposed between the first and second cables; and
shielding disposed around the third dielectric.

2. The twin axial cable of claim 1, wherein the first dielectric directly contacts the second dielectric.

3. The twin axial cable of claim 1, wherein a distance between the first conductor and the second conductor is independent of the third dielectric.

4. The twin axial cable of claim 1, further comprising a drain wire disposed between the shield and the second dielectric.

5. The twin axial cable of claim 1, further comprising a drain wire disposed radially outside both the shield and the second dielectric.

6. A twin axial cable comprising:
a first conductor surrounded by a first dielectric;
a second conductor surrounded by a second dielectric and is axially aligned with the first conductor so that the first dielectric is directly contacting the second dielectric along an axial length;
a third dielectric enclosing the first and second cables but not disposed to increase a distance between the first and second conductors; and
shielding disposed around the third dielectric.

7. The twin axial cable of claim 6, wherein the first dielectric directly contacts the second dielectric.

8. The twin axial cable of claim 6, wherein a distance between the first conductor and the second conductor is independent of the third dielectric.

9. The twin axial cable of claim 6, further comprising a drain wire disposed between the shield and the second dielectric.

10. The twin axial cable of claim 6, further comprising a drain wire disposed radially outside both the shield and the second dielectric.

11. A method of manufacturing a twin axial cable, the method comprising:
surrounding a first conductor with a first dielectric;
surrounding a second conductor with a second dielectric;
axially aligning the first and second conductors so that the first dielectric is directly contacting the second dielectric along an axial length;
enclosing the first and second cables with a third dielectric so that the third dielectric is not disposed therebetween so as to not increase a distance between the first and second conductors; and
disposing a shielding around the third dielectric.
